(19) United States
(12) Patent Application Publication
(10) Pub. No.: US 2025/0125904 A1
(43) Pub. Date: Apr. 17, 2025

(54) APPARATUS AND METHODS FOR SOURCE CODING AND CHANNEL CODING OF LOW ENTROPY SIGNALS

(71) Applicant: Huawei Technologies Co., Ltd., Shenzhen (CN)

(72) Inventor: Mohammadhadi Baligh, Ottawa (CA)

(21) Appl. No.: 18/973,946

(22) Filed: Dec. 9, 2024

Related U.S. Application Data
(63) Continuation of application No. PCT/CN2022/097760, filed on Jun. 9, 2022.

(51) Int. Cl. H04L 1/00

(52) U.S. Cl. CPC H04L 1/0023; H04L 1/0009; H04L 1/0033

(57) ABSTRACT

Signaling that indicates information associated with variable length source coding at a first communication device is communicated between a first communication device to a second communication device in a wireless communication network. Variable length source coded data to which channel coding has been applied is also transmitted by the first communication device to the second communication device, and received from the first communication device by the second communication device. This type of source coding approach may be particularly useful for low entropy signals.

### CROSS-REFERENCE TO RELATED APPLICATIONS

This application is a continuation of International Application No. PCT/CN2022/097760, filed on Jun. 9, 2022, the disclosure of which is hereby incorporated by reference in its entirety.

### TECHNICAL FIELD

The present application relates generally to wireless communications, and more specifically to source coding and channel coding for use in wireless communications systems.

### BACKGROUND

In some communication scenarios or applications such as group acknowledgement (ACK)/negative ACK (NAK) signaling, there is a need to signal a series of bits corresponding to respective decoding results of packets in a sequence. The series of bits are not fully random and equiprobable in this scenario. For example, an ACK rate may be much higher than a NAK rate, or ACK/NAK bits to be signaled are not independent. Under such scenarios, transmitting individual bits is not likely near optimal.

For example, some existing group ACK/NAK procedures cover only very short lengths of bit sequences to be coded, where utilizing the lower entropy that is caused by not fully random ACK/NAK bits tends not to be beneficial.

Huffman coding was proposed in 1952 for generating optimum variable length source coding for low entropy signals that include symbols having unequal probability. However, Huffman coding may generate coded sequences with very large codewords. Moreover, variable length codewords generated by variable length source coding may present a challenge for many channel coding approaches.

There remains a need for effective source coding and channel coding, especially for low entropy signals.

### SUMMARY

Embodiments disclosed herein encompass two aspects of low entropy signaling, namely source coding and channel coding. Some embodiments use source coding that is based in part on Huffman coding but with modifications, in order to generate variable length codewords, with or without a limit on the codeword length. Source coding may or may not be a lossy source coding.

Further, variable length codewords from source coding are encoded using a fixed length channel code in some embodiments, using padding of codewords with known fixed or pseudo random sequences. This type of approach allows for some a priori information to be used for decoding.

According to an aspect of the present disclosure, a method involves communicating signaling that indicates information associated with variable length source coding at a first communication device. The signaling is communicated by the first communication device with a second communication device in a wireless communication network. Such a method may also involve transmitting, by the first communication device to the second communication device, variable length source coded data to which channel coding has been applied.

Another method disclosed herein involves communicating signaling, with a first communication device by a second communication device in a wireless communication network. The signaling, as above, indicates information associated with variable length source coding at the first communication device. This method may also involve receiving, from the first communication device by the second communication device, variable length source coded data to which channel coding has been applied.

In these example methods, and other embodiments herein, communicating signaling may involve transmission of signaling, reception of signaling, or both.

Apparatus embodiments are also disclosed. For example, an apparatus may include a processor and a non-transitory computer readable storage medium that is coupled to the processor. The non-transitory computer readable storage medium stores programming for execution by the processor.

In an embodiment, the programming includes instructions to communicate signaling by a first communication device with a second communication device in a wireless communication network, and the signaling indicates information associated with variable length source coding at the first communication device. The programming may also include instructions to transmit, from the first communication device to the second communication device, variable length source coded data to which channel coding has been applied.

In another embodiment, the programming includes instructions to communicating signaling, with a first communication device by a second communication device in a wireless communication network, and to receive, from the first communication device by the second communication device, variable length source coded data to which channel coding has been applied. As in other embodiments, the signaling indicates information associated with variable length source coding at the first communication device.

The present disclosure also encompasses computer program product embodiments. A computer program product may include a non-transitory computer readable medium storing programming. The programming includes, in some embodiments, instructions to communicate signaling by a first communication device with a second communication device in a wireless communication network, and to transmit, from the first communication device to the second communication device, variable length source coded data to which channel coding has been applied. According to another embodiment, the programming includes instructions to communicate signaling with a first communication device by a second communication device in a wireless communication network, and to receive, from the first communication device by the second communication device, variable length source coded data to which channel coding has been applied.

As in other embodiments, the signaling in these example apparatus embodiments and computer program product embodiments indicates information associated with variable length source coding at the first communication device.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 is a block diagram illustrating, in part, an example receiver according to an embodiment.

FIG. 6 is a signal flow diagram that is illustrative of methods related to communicating signaling and data in a wireless communication network, according to example embodiments.

### DETAILED DESCRIPTION OF ILLUSTRATIVE EMBODIMENTS

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

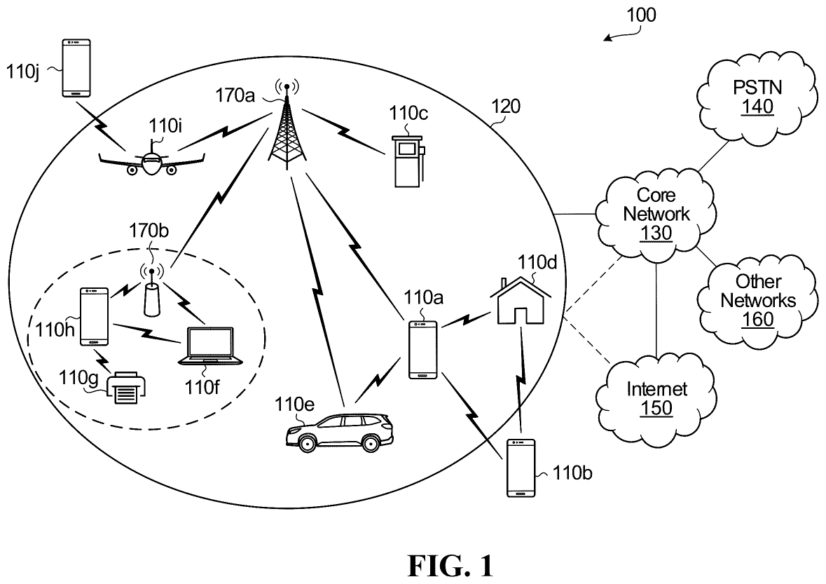

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

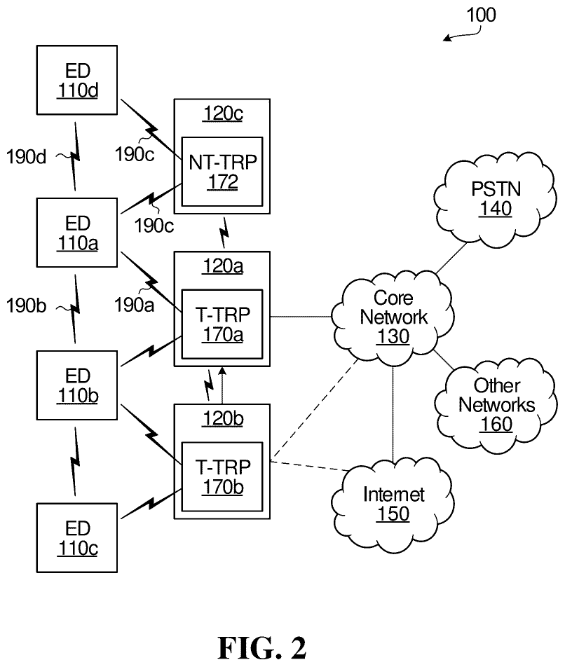

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, the ED 110d may communicate an uplink and/or downlink transmission over an non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 175 for multicast transmission.

The RANs 120a and 120b are in communication with the core network 130 to provide the EDs 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the EDs 110a, 110b, 110c or both, and (ii) other networks (such as the PSTN 140, the Internet 150, and the other networks 160). In addition, some or all of the EDs 110a, 110b, 110c may include functionality for communicating with different wireless networks over different wireless links using different wireless technologies and/or protocols. Instead of wireless communication (or in addition thereto), the EDs 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The EDs 110a, 110b, 110c may be multimode devices capable of operation according to multiple radio access technologies and may incorporate multiple transceivers necessary to support such.

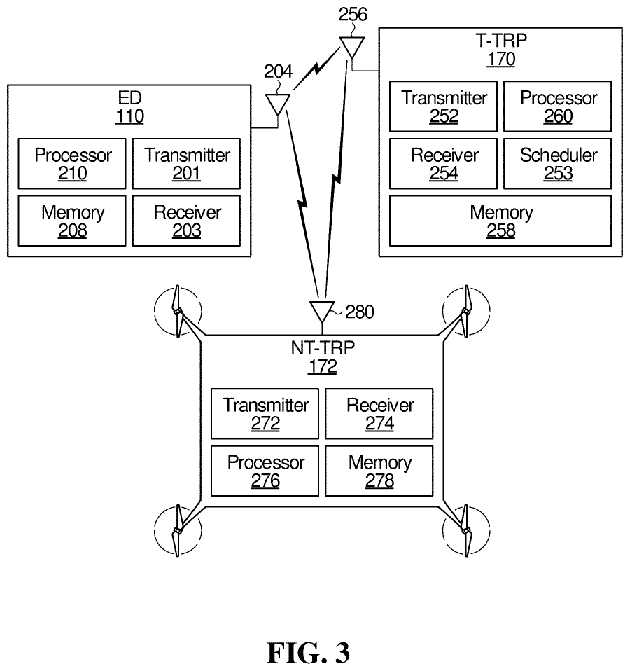

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IoT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or apparatus (e.g., communication module, modem, or chip) in the forgoing devices, among other possibilities. Future generation EDs 110 may be referred to using other terms. The base stations 170a and 170b each T-TRPs and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., the in memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a remote radio head, a terrestrial node, a terrestrial network device, a terrestrial base station, a base band unit (BBU), a remote radio unit (RRU), an active antenna unit (AAU), a remote radio head (RRH), a central unit (CU), a distribute unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses antennas 256 for the T-TRP 170, and may be coupled to the equipment that houses antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU or an ASIC.

Notably, the NT-TRP 172 is illustrated as a drone only as an example, the NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

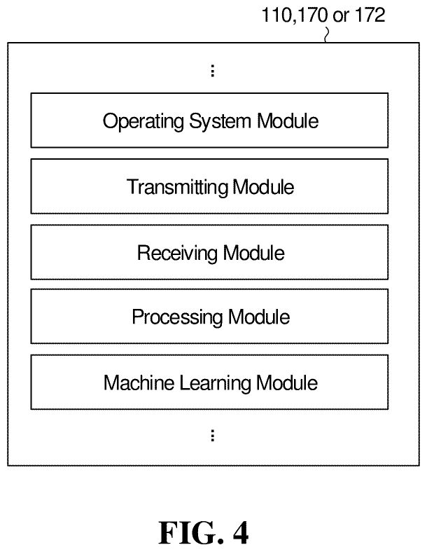

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the EDs 110, the T-TRP 170 and the NT-TRP 172 are known to those of skill in the art. As such, these details are omitted here.

Having considered communications more generally above, attention will now turn to particular example embodiments, which relate primarily to source coding and channel coding.

As used herein, source coding refers to a type of encoding that has a general objective of representing source data with fewer bits. Put another way, source coding may be intended to represent source data with a lower bit rate. Source coding may also or instead be referred to as source data compression or bit rate reduction, for example. Channel coding refers to a type of encoding that has a general objective of protecting data during transmission, by adding redundancy to data that is to be transmitted for example. In the context of the present disclosure, the data to be transmitted may be or include source data that has been source coded. Channel coding enables detection and correction of errors that are introduced during transmission from a transmitting device to a receiving device, and may also or instead be referred to as error detection and correction coding, error correction coding, forward error correction, or error control coding, for example.

Embodiments disclosed herein may involve any of various features. Some embodiments, for example, may involve source codeword probability setup.

Variable length source coding as used in some embodiments may be lossy or lossless. In an ACK/NAK signaling application, for example, lossy coding may be used to identify an error or failure condition based on a number or rate of NAKs significantly exceeding an expected number or rate of NAKs, such as a rate of more than 40% NAKs when only 10% of NAKs is expected.

In some embodiments, a length cap is applied in variable length source coding. Other possible options for variable length coding include one step or two step coding, which may encompass, for example, one step variable length coding, two step fixed plus conditional fixed length coding, and two step variable plus conditional fixed length coding.

Channel coding in some embodiments involves padding of variable-length codewords from source coding. Padding may involve using what are referred to herein as “almost frozen” bits for padding. Combined or separate channel coding may be used for two step source coding.

Source coding and channel coding are described by way of example herein, and illustrative examples relate to a string of low entropy bits such as 40 ACK/NAK bits, with a low expected NAK rate of 0.1 (10% NAK), corresponding to an ACK rate of 0.9 or 90%. ACK/NAK signaling is an example, and embodiments are not restricted to ACK/NAK signaling. There are other types of low entropy bits for which embodiments may be beneficial, such as correlated bits for example.

Turning now to source coding and source codeword probability setup, Huffman coding requires sorting of codewords based on their probabilities. Also, every time two codewords are combined, the new codeword set has to be ranked again. The repetition of this algorithm results in a binary tree. A binary tree is a tree with one root and two branches at any node labelled by 0 and 1 respectively, while each branch can be further divided into two other branches. All codewords are assigned throughout the algorithm to final branches, which are defined as branches that are no longer divided. The source coded string for each codeword is the concatenation of the binary label of all the branches connecting a final branch to the root of the binary tree. In many scenarios, codewords may have the same probability, or probabilities that are so close that they can be assumed or considered to be the same. Arbitrary ordering of these codewords results in different Huffman codes with the same performance. A Huffman encoder and decoder should use the same ordering strategy.

In order to reduce the complexity of building a Huffman code relative to complexity associated with traditional Huffman coding as originally proposed by Huffman, according to an aspect of the present disclosure codewords with the same probability, or similar probabilities, can be put into groups, also referred to herein as bins. A binning strategy to reduce complexity of Huffman coding, while retaining other aspects of a Huffman code binary tree, is described by way of example below.

As an example, all the possible combinations of independent ACK/NAK streams of length 40 containing three NAK bits and 37 ACK bits have a probability of (0.1)³(0.9)³⁷, using the above example of 0.1 and 0.9 rates for NAK and ACK, respectively. The number of such sequences is (₃⁴⁰)=9880. The total number of codewords in this example of length 40 is 2⁴⁰, which is more than 1 trillion codewords. These codewords may be divided or distributed among 41 bins based on the number of NAK bits that each codeword includes. The first bin and the last bin in this case each include only one codeword, with the all-ACK sequence of probability of (0.9)⁴⁰ and the all-NAK sequence with probability of (0.1)⁴⁰. For a correlated stream, the codewords with equal probability do not necessarily have the same numbers of bits of value 1 or 0. For example, if an ACK/NAK burst is highly correlated and modeled by a first order Markov chain, then the bins may have codewords with different numbers of bits of value 1 in them. In any case, if codewords (also referred to as events in this example) that have slightly different probabilities are put into the same bin, then the probability of each codeword in that bin may be assumed or considered to be a probability associated with the bin, such as the average probability of all the codewords in that bin.

Separating, dividing, or distributing codewords among bins, or more generally associating codewords with bins, may be referred to as source codeword group binning. Codewords are in effect put into bins, with each bin containing events that have the same probability, or different probabilities that are presumed or considered to be the same probability for the purpose of binning. Bins may be ranked based on probability of the codewords in the bins. The codewords in each bin may also be ranked inside each bin, and there are various ways to accomplish this. For example, one option is to rank the codewords based on the location of codeword bits that are 1. Consider a bit sequence S1 that has a bit value 1 in locations 10, 18, and 25, and a bit sequence S2 with a bit value 1 in locations 10, 20, and 27. S1 may be ranked as higher because it has a first 1 value in the same location as S2 for its second 1 value appears earlier than in S2. This is just one example, and any other unambiguous ranking inside a bin is also possible.

In low entropy sequences, there may be many low probability codewords. Out of 2⁴⁰ codewords in the above ACK/NAK example, the probability of the number of NAKs higher than 14 is 3e⁻⁶. This represents 96% of the total codewords. In a lossy source coding scenario, all the sequences in the bins that are below a threshold are removed and one event with probability equal to sum of all of those events is created. In the example above, the number of bins will reduce to 16. The first 15 bins, for all-ACK and decreasing by one ACK bit per bin up to 14 NAK bits, remain as in an example provided above. The last bin may be a bin that has one codeword inside and a probability of all of the eliminated codewords. In this example, the eliminated codewords have more than 14 NAK bits. It should be noted, however, that this singular “last bin” for all of the eliminated codewords might not necessarily remain the last bin after bin sorting.

Such a singular bin illustrates how optional lossy source coding may be used to identify an error or failure in some embodiments, based on a much higher than expected NAK rate in this example. More generally, lossy source coding may be useful for identifying an error or failure condition in applications other than ACK/NAK signaling, or for identifying other conditions that may be associated with a higher or lower than expected frequency of source codewords.

A Huffman code guarantees an average codeword length close to entropy, but maximum length grows logarithmically with the lowest probability of all events. In order to cap codeword length, a lower bound may be applied to all probabilities of all codewords having a length below the cap. For example, if the cap is set to 45 bits, no codeword should have a probability of 2-45. As such, all codewords with probability lower than this are set to this probability value. However, the total probability of all codewords should remain at 1, and accordingly all probabilities may be scaled to fulfill this condition. This procedure may be performed multiple times until no codeword has a probability lower than the minimum or threshold probability associated with the cap, and the sum of all probabilities is 1.

After such lower bounding procedure, some bins may have the same probability and may or may not be merged. In the case of merging bins, codeword order may remain intact or codewords within a new merged bin may be reordered based on an unambiguous ranking.

Huffman coding is defined based on events and at each step, the number of codewords becomes 1 shorter. In other words, Huffman coding requires 2⁴⁰−1 steps in the above example of a sequence of 40 bits. In a binned case, complexity is proportional to the number of bins, and a recursive procedure is applied in source coding until only one bin remains with only one element.

All bins are used in a first iteration, denoted herein as t=1, and in subsequent iterations (t>1) the bins remaining at the end of the preceding iteration t−1 are used.

At any iteration t, one of these cases applies:

(1) The bin with the lowest element probability has an even number of elements (2K), each with probability p. Every two consecutive elements in the bin are combined to create K elements with probability 2p. All of the new elements go to a new bin with element probability of 2p and the original bin is removed. The new bin is ranked in order within other bins based on its probability. If the new bin has a probability the same as an older bin, then the new bin may be ranked before or after the older bin, or merged with the older bin by placing the new elements of the new bin at the bottom or top (or any other unambiguous location such as the middle) of the older bin. A solution of placing the new elements of the new bin at the top of the older bin or in a new bin above the existing older bin often creates codes with possibly lower maximum code lengths without changing the overall average code length. The number of bins is now the same as or lower than at the beginning of the iteration but the total number of codewords is now reduced by K.

(2) The bin with the lowest element probability has an odd number of elements and more than one element (2K+1>1), each with probability p. Every two consecutive elements in the bin are combined, except the first element (or last element, or any other unambiguous element), to create K elements with probability 2p. All of the new elements go to a new bin with element probability of 2p and the original bin remains with only its non-combined element with probability p. The new bin is ranked order within other bins based on its probability. If the new bin has a probability the same as an older bin, then the new bin may be ranked after or before the older bin or merged with the older bin by placing the new elements of the new bin at the bottom or top (or any other unambiguous location such as the middle) of the older bin. The latter solution, of placing the new elements of the new bin at the top of the older bin, often creates codes with possibly lower maximum code lengths. The number of bins is now the same as or one higher than at the beginning of the iteration but the total number of codewords is now reduced by K.

(3) The bin with the lowest element probability has only one element with probability p₁ and the bin currently ranked just above it has probability p₂>p₁. The element with probability p₁ is combined with the lowest ranked element in the bin with probability p₂ to create a new element with probability p₁+p₂ in a new bin with only one element. The new bin is ranked in order within the other bins based on its probability. If the new bin has a probability the same as an older bin, then the new bin may be ranked after or before the older bin or merged with the older bin by placing the new element at the bottom or top of the older bin. The latter solution, of placing the new element at the top of the older bin, often creates codes with possibly lower maximum code lengths. The number of bins is now the same as or lower than at the beginning of the iteration, but the total number of codewords is now reduced by one.

Iterations are performed until all codewords are counted for, or in other words until only one codeword remains.

The end result of this example iterative approach is a Huffman-like tree, that may be used in substantially the same way as a Huffman tree according to original Huffman coding as proposed by Huffman, or potentially other Huffman-based coding approaches.

This is one example of source coding, which encompasses several embodiments related to different binning approaches.

Some embodiments involve two step source coding. In an embodiment, a first step involves encoding bin number and a second step involves encoding among the bins. Consider an example of M bins, each having Kₘ, m=1, . . . , M elements. Source bits may then be encoded into codewords that include two parts. The first part may include a fixed length codeword with └log₂ M┘ bits or a variable length codeword (from Huffman-based coding for example) indicating the bin number. The second part may be or include a conditional fixed or variable length codeword indicating an index or other identifier of a codeword inside the bin. In a conditional fixed length case Lₘ=└log₂ Kₘ┘ bits are used to uniquely identify the elements in the same bin. A coding approach can be as simple as assigning unique integer indexes between 0 to 2^{L}^{ₘ}⁻¹ to the Kₘ elements inside that bin, with each index represented by dec2bin(i, Lₘ), where dec2bin(i, Lₘ) is the representation of integer i using Lₘ bits. In a variable length case, suppose that there are 2Kₘ−2^{L}^{ₘ} codewords with length Lₘ and 2^{L}^{ₘ}−Kₘ codewords with length Lₘ−1. One coding approach in this case is to use, for codewords in the bin indexed i=0, . . . , 2^{L}^{ₘ}−Kₘ−1, a codeword Cᵢ=dec2bin(i, Lₘ−1), and use, for codeword indexes i=2^{L}^{ₘ}−Kₘ, . . . , Kₘ−1, a codeword Cᵢ=dec2bin(i+2^{L}^{ₘ}−Kₘ, Lₘ).

These are examples of two step source coding. Another example involves encoding weight of a codeword in a first source coding step, and bit value locations in a second source coding step. A source codeword then includes a first part that encodes or indicates codeword weight and a second part indicating locations or positions of a certain bit value. For example, for ACK/NAK signaling, codeword weight is related to the number of errors (NAKs), and this type of two step source coding may involve encoding the number of errors and error locations, to generate codewords that include a first part that encodes or indicates the number of errors and a second part that encodes or indicates the locations or positions of the errors. Another option that may be particularly useful for consecutive bit values that are the same, such as ACK/NAK signaling for bursty errors, involves two step coding for start location and the length of the consecutive same bit values. For ACK/NAK signaling for example, two step source coding may involve encoding the start location or position, and length, of consecutive NAK values, or encoding the start location or position, and length, of consecutive ACK values, to generate codewords that include a first part that encodes or indicates a start location or position and a second part that encodes or indicates a length of consecutive values that are the same. Another example is encoding start and end locations or positions of a run of consecutive bits of the same value, to generate source codewords that include a first part that encodes or indicates a start location or position and a second part that encodes or indicates an end location or position of consecutive values that are the same.

Other embodiments of two step source coding are possible.

Source coding may create codewords of different lengths, which are not suitable for channel coding techniques that require a fixed bit length as input for channel coding. With a Huffman code or other near optimal variable length source coding, each source codeword probability is approximately inversely proportional exponentially with its length, i.e. pᵢ∝2^{-L}^{ᵢ}, where pᵢ, Lᵢ are the probability and length of source coded codewords, respectively. Therefore, shorter codewords have higher probability. It may be desirable to provide better protection for these shorter source codewords. By padding shorter codewords with a known sequence, which can be all 0s, all is, a pseudo random sequence, or any other unambiguous sequence, the length of all codewords for channel coding is equal. Adding a known sequence to a codeword makes it more protected. The shorter, more probable codewords are better protected by enhancing the Voronoi region of the codeword that will be channel coded. Voronoi region here is defined as the area of the multi-dimensional space of the received noisy signal at a receiver, that maps to the specific codeword after all the channel decoding has been completed.

As an example, suppose that source coding produced the following codewords: 0 with probability 45%, 10 with probability 35%, and 11 with probability 20%. Padding the first codeword with a 0 makes that bit to be almost frozen, with probability 80% (total probability of 45%+35% that the last bit is 0), while the first bit after padding is not frozen (45% for 0 and 55% for 1). In effect, the new codewords for channel coding, after padding, are 00, 10 and 11. The receiver while performing channel decoding can ignore the possibility of the 01 codeword and hence improve protection of the three possible codewords, especially codeword 00.

The probability of each source codeword and its length are related almost as L log₂(1/p). By padding C−L bits to source codewords, the Voronoi region of the codewords with probability p increases by 2^{C-L}≅p2^{C}. In other words, the Voronoi region of each codeword is enhanced approximately proportional to its probability.

After padding, the length of all padded codewords for channel encoding is the same, and any channel code that handles fixed length inputs can be used. Although padded bits may have any value, a padding sequence of all 0s may be preferred for potential benefits at a receiver as described at least below. However, padding sequences other than an all-0s sequence are possible.

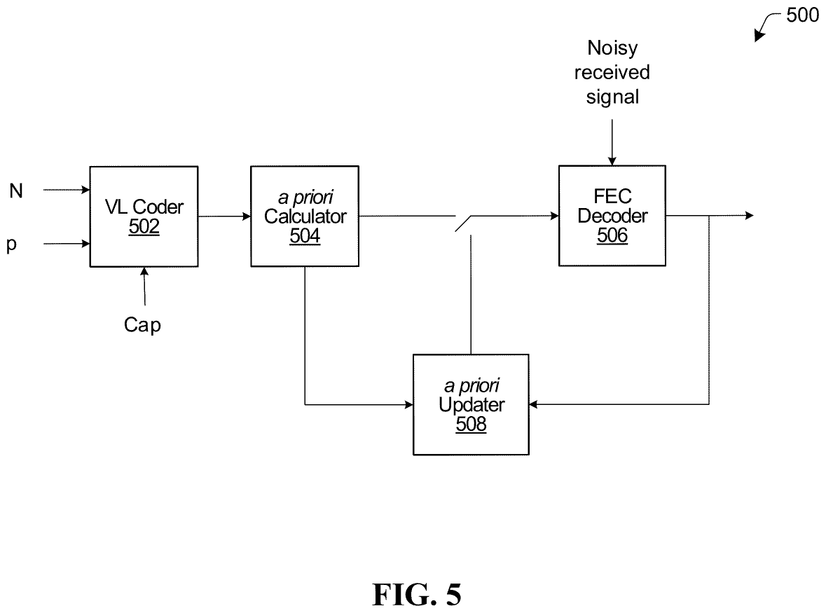

It is noted that padded bits are not equiprobable, and are not independent. For padding with an all-0s sequence, the padded bits when received at a receiver are more likely be 0, and also toward the end of a codeword where padded bits would be added, received bits are more likely to be 0. Padded bits may therefore also be referred to as almost frozen bits. If an almost frozen bit is 0, then this also increases the probability that other frozen bits are 0. This can be used in a receiver to potentially improve receiving performance. FIG. 5 is a block diagram illustrating, in part, an example receiver according to an embodiment.

The example receiver 500 includes a variable length (VL) coder 502, an a priori calculator 504, a forward error correction (FEC) decoder 506 as an example of a channel decoder, and an a priori updater 508, which are coupled together as shown. These components may be implemented using hardware, one or more components that executed software, or a combination thereof.

In the example receiver 500, the channel decoder uses the code length and probability of each bit to know how the Huffman code is performed. In case of other usages, or other codes, what is important to the a priori calculator 504, is to determine the probability of each bit in the padded codeword to be 0. That is used by the FEC decoder 506 in this example to determine the codeword that was transmitted by the transmitter. For example, in a FEC decoder which uses log-likelihood ratio (LLR) as an example, the a priori LLR value is defined by log p₀/p₁, where p₀ and p₁ are the probability of any bit position at the source coded stream to be 0 and 1, respectively. This LLR value is added to the input LLR to utilize the a priori knowledge gained from the source coding. For improved performance, the soft decision output of the FEC decoder 506 may be used to update the probability due to correlation of the almost frozen bits. This is represented in FIG. 5 by the a priori updater 508, and may also or instead be referred to as soft successive probability update. In the case of LLR-based decoders, the additional information can be demonstrated by the change in the a priori LLR in accordance to the change in the probability of each almost frozen bit being 0 or 1. Further iterations can improve decoding performance of the FEC decoder 506.

Source coding may involve two step coding in some embodiments, as described elsewhere herein. Channel coding for two step source coding may involve single step channel coding or two step channel coding.

For example, two source codeword parts may be combined or treated as one input source codeword for channel coding, and be channel coded in one channel coding step to generate one channel coded codeword. The combined source codeword may still be of variable length, in which case source codeword padding may be used prior to channel coding. For two step source coding with a conditional fixed length second coding step, for example, combining a first fixed or variable length codeword part with a second conditional fixed length codeword part still results in variable length source codewords. This is due to the fact that if the second part uses conditional fixed length, the receiver is not aware of the length of the second part until it decodes the first part which is intertwined with the second part through channel coding.

Alternatively, the two parts of a source codeword may be individually channel coded, and a receiver decodes the two source codewords. For example, the receiver may decode the first part to recover a bin number, and then decode the second part based on the decoded bin number. In this example, once the bin number is recovered, the second part is of known length because all of the source codewords in the bind are of length Lₘ=└log₂ Kₘ┘, and therefore the receiver can perform fixed length decoding.

Consider an example in which there are N=40 bits with probability of being 1 as 0.1, independent of each other. In this example, the total entropy is 18.82 bits, which is less than half of the number of bits. Different combinations of features disclosed herein, and impacts on the encoding and decoding processes, are examined below.

As a comparative example, according to fixed length coding, 40 source coded bits are used.

In one embodiment, source codeword binning and lossy source coding with A=15 are used. In this embodiment, A is the number of non-combined bins. All of the bins with a number of is from 0 to 14 are kept, and if the number of is in a codeword is 15 or above, the codewords are merged into one single codeword. In this case, codeword length is up to 36 bits.

Another embodiment that may be referred to as Lossless Huffman-based source coding involves source codeword group binning, ranking within bins, iterative bin-based source coding, padding, and channel coding of padded source codewords. This combination of features provides a variable length code with average source coded bit length of 18.79 and maximum length of 130 bits. Codeword length may be capped, to a maximum of 50 bits for example, to provide a slightly higher average codework length of 18.82 bits but with a maximum length reduced to 50. A cap of 45 bits reduces the maximum length further to 44, but with a higher average length of 19.62 bits.

According to an embodiment that may be referred to as Lossy Huffman-based source coding, lossy source coding is added to the preceding embodiment. With A=15, for example, maximum length is reduced to 47 bits. Also, if combined with a length cap of 45 bits, the maximum length is further reduced without significant impact on average length.

Yet another embodiment involves two step source coding with single step channel coding. Such an embodiment may involve source codeword group binning, ranking within bins, lossy source coding, iterative bin-based source coding, two step source coding, and single step channel coding, with 6 source code bits for bin number and a conditional fixed number of bits between 0 bits to 38 bits. However, average code length becomes 6+16.38=22.38 bits and the maximum length of 38+6=44. Using a lossy code with A=15 reduces the fixed part to 4 bits and the maximum length of the conditional case to 34+4=38 bits.

An embodiment of two step source coding with two step channel coding may involve source codeword group binning, ranking within bins, lossy source coding, ranking within bins, two step source coding, and two step channel coding with two codes. The first part of a channel codeword in this example is 6 bits for lossless or 4 bits for lossy, and the second part is conditioned on the first part and has variable length between 0 and 38 bits.

As a final example, consider two step source coding with single step channel coding and variable length bin coding. Such an approach may involve source codeword group binning, ranking within bins, lossy source coding, iterative bin-based source coding, two step source coding, and single step channel coding, with Huffman coding applied for the bin number. In this scenario on average 3 bits will be used for the bin and 16.38 bits for the index inside the bin for a total of average 19.38 bits. The maximum length of the bin index is 11 and the maximum length inside the bin is 38, making the longest codeword 49 bits.

TABLE 1
below summarizes these examples.
Summary of Illustrative Examples.

| | Lossless | | Lossy A = 15 | |
|---|---|---|---|---|
| | Average | Maximum | Average | Maximum |
| Fixed length | 40 | 40 | 36 | 36 |
| Huffman-based | 18.79 | 130 | 18.79 | 47 |
| Length (fixed) and Weight | 6 + 16.38 | 6 + 38 | 4 + 16.38 | 4 + 34 |
| (conditional fixed) | | | | |
| Length (Huffman-based) | 3 + 16.38 | 11 + 38 | | |
| and Weight | | | | |
| (conditional fixed) | | | | |
| Huffman-based | 18.82 | 50 | 18.79 | 47 |
| with cap = 50 | | | | |
| Huffman-based | 19.62 | 44 | 18.80 | 45 |
| with cap = 45 | | | | |

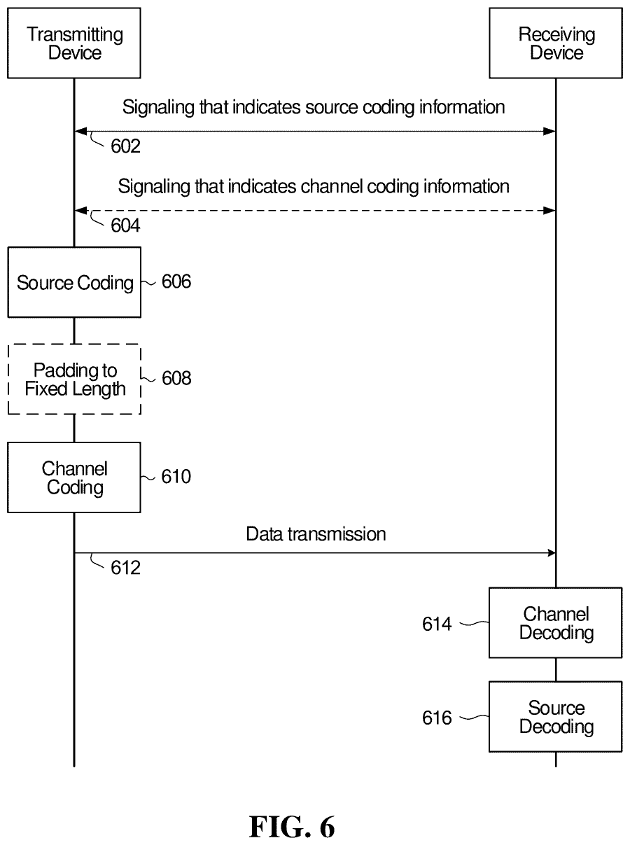

Various embodiments are described herein by way of example. These embodiments encompass, for example, methods related to signaling and data in a wireless communication network, FIG. 6 is a signal flow diagram that is illustrative of such methods according to example embodiments. Features illustrated in FIG. 6 are in the context of a first communication device and a second communication device, shown in the drawing as a transmitting device, which may also or instead be referred to as a transmitter, and a receiving device, which may also or instead be referred to as a receiver. Uplink communications from an electronic device such as a UE to a network device such as a BS, downlink communications from a network device to an electronic device, and direct device-to-device communications such as sidelink communications are contemplated. Therefore, each of the transmitting device and the receiving device may be an electronic device or a network.

From the perspective of the transmitting device in FIG. 6 as a first communication device a method may involve communicating, at 602, signaling that indicates information associated with variable length source coding at the first communication device. The signaling is shown in FIG. 6 as signaling that indicates source coding information. This communicating may involve transmitting the signaling by the first communication device to a second communication device, shown by way of example in FIG. 6 as the receiving device. At the right side in FIG. 6, 602 also illustrates receiving the signaling, from the first communication device by the second communication device. Other embodiments may involve communicating this signaling in other ways. For example, communicating signaling, by a first communication device with a second communication device, may also or instead involve receiving the signaling by the first communication device from the second communication device. Similarly, communicating signaling with a first communication device by a second communication device may also or instead involve transmitting the signaling by the second communication device to the first communication device.

To summarize, references to communicating signaling, by a first communication device with a second communication device in a wireless communication network may include either or both of: transmitting the signaling by the first communication device to the second communication device and receiving the signaling by the first communication device from the second communication device. References to communicating signaling, with a first communication device by a second communication device in a wireless communication network may include either or both of: receiving the signaling from the first communication device by the second communication device and transmitting the signaling to the first communication device by the second communication device. These options for communicating signaling between first and second communication devices may be applied not only to signaling that indicates information associated with variable length source coding at the first communication device, but also or instead to other types of signaling, such as signaling related to channel coding. The double arrows at 602, and also 604, in FIG. 6 are intended to illustrate these options for communicating signaling. Thus, signaling related to source coding and/or channel coding may be transmitted, partially transmitted and partially received, or fully received by the first communication device, and may be received, partially received and partially transmitted, or fully transmitted by the second communication device.

Although the present disclosure is not in any way limited to particular types of signaling, the signaling at 602 and/or 604 may be or include, for example, radio resource control (RRC) signaling. RRC signaling may be used for p, for example, whereas N may be implicit (such as the number of packets) or explicit through PDCCH, PUCCH, MAC CE. For other embodiments, signaling may implicitly or explicitly define codewords and their relative probabilities.

FIG. 6 also shows a data transmission at 612. This is intended to illustrate transmitting by the first communication device to the second communication device, and receiving from the first communication device by the second communication device, variable length source coded data to which channel coding has been applied at 610. As shown in FIG. 6, a method may involve applying source coding to source data at 606, optionally padding variable length source codewords to fixed length at 608, and applying channel coding to source coded data at 610. An interleaver or interleaving (not shown in FIG. 6) may be used after a source encoder that applies the source coding at 606 and/or after a channel encoder that applies the channel coding at 610, to shuffle bits in a source coded and/or channel coded bit stream. At the receive side, channel decoding at 614 and source decoding at 616 represent counterpart operations to the channel coding and source coding at 610, 606, respectively. A deinterleaver or deinterleaving may be used at the receiving device for counterpart operations of the interleaver or interleaving if used at the transmitting device. Although not shown in FIG. 6, receive-side operations or features may include removing padding bits that were added to source codewords at 608.

Regarding the signaling at 602, the information associated with the variable length source coding may include any one or more of: a number of bits for the variable length source coding (also referenced herein by way of example as N), probabilities (also referenced herein by way of example as p), a lossy source coding parameter (also referenced herein by way of example as A), a cap on maximum source codeword length, a number of parts of a source codeword, and one or more parameters of padding of variable length source codewords to fixed length. Parameters of padding may include, for example, a sequence of bits, referred to herein as padding bits or almost frozen bits, by which source codewords are padded at 608.

Although the present disclosure is not in any way limited to particular types of signaling, the signaling at 602 and/or 604 may be or include, for example, radio resource control (RRC) signaling and/or explicit signaling through one or more of physical downlink control channel (PDCCH), physical uplink control channel (PUCCH), and one or more medium access control (MAC) control elements (CEs). In an embodiment, RRC signaling is used for probabilities p, and N may be implicit (such as implied by the number of previously transmitted packets or the number of transmitted PDCCH messages) or explicit through PDCCH, PUCCH, or MAC CE. This example illustrates that signaling that indicates coding information at 602, and/or 604, may involve multiple types of signaling.

Variable length source coding at 606 may enable or otherwise involve lossy source coding as disclosed herein. According to lossy source coding, multiple source codewords that have probabilities less than a threshold are encoded into a single source codeword. For example, as described at least above, there may be many low probability codewords, and all sequences in bins that are below a threshold are removed and one event (codeword) with probability equal to sum of all of those events is created. Thus, the low probability codewords that have been removed are in effect encoded into this one codeword.

Some embodiments apply a cap on source codeword length, and therefore variable length source coded data may have been source coded based on a capped maximum length of source codewords.

Another optional source coding feature is iterative source coding. Variable length source coded data may have been source coded based on iterations and source codeword groups among which source codewords have been divided. For example, the source codewords may have been divided among the source codeword groups and ranked within the source codeword groups based on probabilities of the source codewords. The source codeword groups may have also or instead been ranked based on the source codewords within each of the source codeword groups. A transmit-side method may therefore involve dividing source codewords among the source codeword groups, optionally ranking the source codewords within each of the source codeword groups based on the probabilities of the source codewords, and/or possibly ranking the source codeword groups based on the source codewords within each of the source codeword groups.

Variable length source coded data may be or include multi-part source codewords. Two step source coding and two-part source codewords are disclosed by way of example herein, and features disclosed in the context of two step source coding or two-part source codewords may be extended to higher orders or multi-part source codewords.

Illustrative and non-limiting examples provided herein encompass embodiments in which each two-part source codeword includes:
a first part that encodes a bin number of one of a plurality of source codeword groups among which source codewords have been divided, and a second part that encodes an identifier of a source codeword inside the one of the source codeword groups; or
a first part that encodes a weight of a source codeword and a second part that encodes locations a bit value in the source codeword; or
for ACK/NAK source code data, a first part that encodes a number of errors (NAKs) and a second part that encodes locations of the errors; or
a first part that encodes a start location and a second part that encodes a length of consecutive values in a source codeword that are the same; or
a first part that encodes a start location and a second part that encodes an end location of consecutive values in a source codeword that are the same.

With multi-part source coding or multi-part source codewords, channel coding may involve single step channel coding or multi-step channel coding. For example, for single step channel coding of two-part source codewords, channel coding may have been applied by the first communication device at 610 to channel encode each two-part source codeword. For two step channel coding of two-part source codewords, channel coding may have been applied by the first communication device at 610 to separately channel encode each part of each two-part source codeword.

Thus, channel coding may have been applied by the first communication device at 610 to channel encode each two-part source codeword, or to separately channel encode each part of each two-part source codeword. In some embodiments, a method may involve communicating (by transmitting and/or receiving as described at least above) signaling that indicates the channel coding to channel encode each two-part source codeword or to separately channel encode each part of each two-part source codeword. This is shown by way of example at 604. This signaling may indicate whether channel coding at 610 is single step channel coding or two step channel coding, or more generally multi-step channel coding. A transmit-side method may involve transmitting and/or receiving the signaling by the first communication device, and a receive-side method may involve receiving and/or transmitting the signaling by the second communication device. This signaling informs the receiving device (or the transmitting device) as to whether the channel coding that had been applied (or is to be applied) to source coded data by the first communication device is single step channel coding or multi-step channel coding, so that the receiving device can properly decode the received data transmission at 614.

Thus, to summarize, the signaling related to channel coding, shown at 604 in FIG. 6, may indicate the channel coding to channel encode each two-part source codeword or to separately channel encode each part of each two-part source codeword, or more generally to encode each multi-part source codeword or to separately channel encode each part of each multi-part source codeword. A method may involve a first communication device that is to transmit data (the transmitting device in FIG. 6) transmitting, partially transmitting and partially receiving, or fully receiving the signaling, and/or a second communication device that is to receive data (the receiving device in FIG. 6) receiving, partially receiving and partially transmitting, or fully transmitting the signaling.

In the context of a transmitting device, this signaling, whether transmitted or received by the transmitting device, may indicate whether the channel coding is to be applied to channel encode two-part (or multi-part) source codewords or separately channel encode each part of each two-part (or multi-part) source codeword. From the perspective of a receiving device that is to receive data, this signaling, whether transmitted or received by the receiving device, may indicate whether the channel coding for a received data transmission would have been applied by the transmitting device to channel encode two-part (or multi-part) source codewords or separately channel encode each part of each two-part (or multi-part) source codeword.

In either case, signaling that is related to channel coding and is shown by way of example at 604, related to channel coding, indicates the channel coding to channel encode source codewords or separately channel encode parts of source codewords. For multi-part source codeword such as two-part codewords, this signaling may indicate the channel coding to channel encode each two-part (or otherwise multi-part) source codeword or to separately channel encode each part of each two-part (or otherwise multi-part) source codeword. In other words, this signaling may indicate whether the channel coding had been applied, for the data transmission 612, to channel encode each two-part source codeword or to separately channel encode each part of each two-part source codeword.

Other channel coding parameters may also or instead be indicated in signaling, at 604 or separately. Examples include code rate and number of channel coded bits, either or both of which may be indicated in signaling.

A transmit-side method may involve padding variable length source coded data to fixed length at 608 for channel coding. Therefore, in some embodiments variable length source coded data would have been padded to fixed length before the channel coding had been applied. Padding of variable length source coded data to fixed length might not only enable certain types of channel coding to be applied, but may also enable the second (receiving) communication device to exploit, in channel decoding, correlations between padding bits with which the source coded data had been padded. This is described at least above by way of example, with reference to FIG. 5.

FIG. 6 illustrates both transmit-side method features and receive-side method features. Any features described in the context of a transmitting method or transmit-side method may be implemented in or adapted to a receiving method or receive-side method.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor and a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to, or to cause a processor to, communicate, by a first communication device with a second communication device in a wireless communication network, signaling that indicates information associated with variable length source coding at the first communication device; and transmit, from the first communication device to the second communication device, variable length source coded data to which channel coding has been applied. For a receiving device or receive-side implementation, programming stored in or on a non-transitory computer readable storage medium may include instructions to, or to cause a processor to, communicate, with a first communication device by a second communication device in a wireless communication network, signaling that indicates information associated with variable length source coding at the first communication device; and receive, from the first communication device by the second communication device, variable length source coded data to which channel coding has been applied.

Embodiments related to apparatus or non-transitory computer readable storage media may include any one or more of the following features, for example, which are also discussed elsewhere herein:
the information associated with the variable length source coding may be or include any one or more of: a number of bits for the variable length source coding, probabilities, a lossy source coding parameter, a cap on maximum source codeword length, a number of parts of a source codeword, and one or more parameters of padding of variable length source codewords to fixed length;
the variable length source coding may enable lossy source coding, into a single source codeword, for multiple source codewords that have probabilities less than a threshold;
the variable length source coded data may have been source coded based on a capped maximum length of source codewords;
the variable length source coded data may have been source coded based on multiple iterations and source codeword groups among which source codewords have been divided;
the source codewords may have been divided among the source codeword groups and ranked within the source codeword groups based on probabilities of the source codewords;
the source codeword groups may have been ranked based on the source codewords within each of the source codeword groups;
the variable length source coded data may be or include two-part source codewords;
each two-part source codeword may be or include a first part that encodes a bin number of one of a plurality of source codeword groups among which source codewords have been divided, and a second part that encodes an identifier of a source codeword inside the one of the source codeword groups;
each two-part source codeword may be or include a first part that encodes a weight of a source codeword and a second part that encodes locations a bit value in the source codeword;
each two-part source codeword may be or include, for ACK/NAK source code data, a first part that encodes a number of errors and a second part that encodes locations of the errors;
each two-part source codeword may be or include a first part that encodes a start location and a second part that encodes a length of consecutive values in a source codeword that are the same;
each two-part source codeword may be or include a first part that encodes a start location and a second part that encodes an end location of consecutive values in a source codeword that are the same;
the channel coding may have been applied to channel encode each two-part source codeword;
the channel coding may have been applied to separately channel encode each part of each two-part source codeword;
the programming further includes instructions to, or to cause a processor to, communicate, by the first communication device with the second communication device, (or communicate, with the first communication device by the second communication device) signaling that indicates the channel coding to channel encode each two-part source codeword or to separately channel encode each part of each two-part source codeword;
the variable length source coded data may have been padded to fixed length before the channel coding had been applied;
the variable length source coded data may have been padded to fixed length enables the second communication device to exploit, in channel decoding, correlations between padding bits with which the source coded data had been padded.

Although this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

For example, although ACK/NAK signaling is referenced herein, embodiments are not in any way limited to this illustrative example, and can be applied to other short to medium length signals with low entropy. Other applications such as sensor reporting, for example, may also or instead benefit from the embodiments disclosed herein.

Features disclosed herein in the context of method embodiments, for example, may also or instead be implemented in apparatus or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although aspects of the present invention have been described with reference to specific features and embodiments thereof, various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

What is claimed is:

1. A method comprising:
communicating, by a first communication device with a second communication device in a wireless communication network, signaling that indicates information associated with variable length source coding at the first communication device; and
transmitting, by the first communication device to the second communication device, variable length source coded data to which channel coding has been applied.

2. The method of claim 1, wherein the information associated with the variable length source coding comprises any one or more of: a number of bits for the variable length source coding, probabilities associated with the variable length source coding, a lossy source coding parameter, a cap on maximum source codeword length, a number of parts of a source codeword, or one or more parameters of padding of variable length source codewords to fixed length.

3. The method of claim 1, wherein the variable length source coding enables lossy source coding, into a single source codeword, for a plurality of source codewords that have probabilities less than a threshold.

4. The method of claim 1, wherein the variable length source coded data having been source coded based on a capped maximum length of source codewords.

5. The method of claim 1, wherein the variable length source coded data having been source coded based on a plurality of iterations and source codeword groups among which source codewords have been divided.

6. The method of claim 1, wherein the variable length source coded data comprises two-part source codewords.

7. The method of claim 1, wherein the variable length source coded data having been padded to fixed length before the channel coding had been applied.

8. A method comprising:
communicating, with a first communication device by a second communication device in a wireless communication network, signaling that indicates information associated with variable length source coding at the first communication device; and
receiving, from the first communication device by the second communication device, variable length source coded data to which channel coding has been applied.

9. The method of claim 8, wherein the information associated with the variable length source coding comprises any one or more of: a number of bits for the variable length source coding, probabilities associated with the variable length source coding, a lossy source coding parameter, a cap on maximum source codeword length, a number of parts of a source codeword, or one or more parameters of padding of variable length source codewords to fixed length.

10. The method of claim 8, wherein the variable length source coding enables lossy source coding, into a single source codeword, for a plurality of source codewords that have probabilities less than a threshold.

11. The method of claim 8, wherein the variable length source coded data having been source coded based on a capped maximum length of source codewords.

12. The method of claim 8, wherein the variable length source coded data having been source coded based on a plurality of iterations and source codeword groups among which source codewords have been divided.

13. The method of claim 8, wherein the variable length source coded data comprises two-part source codewords.

14. The method of claim 8, wherein the variable length source coded data having been padded to fixed length before the channel coding had been applied.

15. A first apparatus comprising:
at least one processor; and
a non-transitory computer readable storage medium, coupled to the at least one processor, storing programming for execution by the at least one processor, the programming including instructions to:
communicate, with a second apparatus in a wireless communication network, signaling that indicates information associated with variable length source coding at the first apparatus; and
communicate, with the second apparatus, variable length source coded data to which channel coding has been applied.

16. The first apparatus of claim 15, wherein the information associated with the variable length source coding comprises any one or more of: a number of bits for the variable length source coding, probabilities associated with the variable length source coding, a lossy source coding parameter, a cap on maximum source codeword length, a number of parts of a source codeword, or one or more parameters of padding of variable length source codewords to fixed length.

17. The first apparatus of claim 15, wherein the variable length source coding enables lossy source coding, into a single source codeword, for a plurality of source codewords that have probabilities less than a threshold.

18. The first apparatus of claim 15, the variable length source coded data having been source coded based on a capped maximum length of source codewords.

19. The first apparatus of claim 15, wherein the instructions to communicate the variable length source coded data comprise instructions to transmit, by the first apparatus to the second apparatus, the variable length source coded data to which channel coding has been applied.

20. The first apparatus of claim 15, wherein the instructions to communicate the variable length source coded data comprise instructions to receive, by the first apparatus from the second apparatus, the variable length source coded data to which channel coding has been applied.
